(19) United States
(12) Patent Application Publication
(10) Pub. No.: US 2011/0005922 A1
(43) Pub. Date: Jan. 13, 2011

(54) Methods and Apparatus for Protecting Plasma Chamber Surfaces

(75) Inventors: Chiu-Ying Tai, Chelmsford, MA (US); Xing Chen, Lexington, MA (US); Chaolin Hu, North Billerica, MA (US); Andrew Cowe, Andover, MA (US); Ali Shajii, Weston, MA (US)

Correspondence Address: PROSKAUER ROSE LLP, ONE INTERNATIONAL PLACE, BOSTON, MA, 02110, US

(73) Assignee: MKS Instruments, Inc., Andover, MA (US)

(21) Appl. No.: 12/499,453

(22) Filed: Jul. 8, 2009

(51) Int. Cl. C23C 14/34

(52) U.S. Cl. 204/192.25; 204/298.07

(57) ABSTRACT

A method for creating a protective layer over a surface of an object comprising aluminum and magnesium for use in a semiconductor processing system, which includes oxidizing the surface of the object using a plasma electrolytic oxidation process. The method also includes generating a halogen-comprising plasma by exciting a gas comprising a halogen. The method also includes exposing the oxidized surface to the halogen-comprising plasma or excited gas.

### TECHNICAL FIELD

This invention relates generally to plasma generation and processing equipment. In particular, the technology relates to methods and apparatus for protecting plasma chamber surfaces.

### BACKGROUND

Plasmas are often used to activate gases placing them in an excited state so that they have an enhanced reactivity. In some cases, the gases are excited to produce dissociated gases containing ions, free radicals, atoms and molecules. Dissociated gases are used for numerous industrial and scientific applications including processing solid materials such as semiconductor wafers, powders, and other gases. The parameters of the dissociated gas and the conditions of the exposure of the dissociated gas to the material being processed vary widely depending on the application. Significant amounts of power are sometimes required in the plasma for dissociation to occur.

Plasma reactors for processing semiconductor wafers may form a plasma within a chamber containing the wafer, or they may receive excited gases produced by a reactive gas generator located upstream of the chamber. The preferred location of plasma generation relative to the wafer location depends on the process.

A plasma in contact with a wafer generally has higher chemical reactivity due to the presence of electrons and ions in the plasma. When the plasma is in contact with the wafer, it is possible to control the energy and direction of ions at the wafer surface by applying a bias voltage to the wafer. Such arrangements are used in, for example, plasma-enhanced chemical vapor deposition or directional etching applications.

For semiconductor processes in which the workpiece (e.g., wafer) is sensitive to electric charges in a plasma, susceptible to ultraviolet energy (UV) damage generated by the plasma, or require high chemical selectivity, exposing the wafer to the plasma can be undesirable. In some situations, the wafer and the plasma chamber surfaces can be damaged by exposure to chemically corrosive plasmas. This may create chemical contamination and particle generation, shorten the product life and increase cost of ownership. Accordingly, remote plasma sources are sometimes used to reduce wafer and chamber damage because the plasma is generated outside the process chamber and activated gases produced by the plasma are delivered to the processing chamber for processing the wafer.

Reactive gas generators generate plasmas by, for example, applying an electric potential of sufficient magnitude to a plasma gas (e.g., O₂ N₂, Ar, NF₃, F₂, H₂ and He), or a mixture of gases, to ionize at least a portion of the gas. Plasmas can be generated in various ways, including DC discharge, radio frequency (RF) discharge, and microwave discharge. DC discharge plasmas are achieved by applying a potential between two electrodes in a plasma gas. RF discharge plasmas are achieved either by electrostatically or inductively coupling energy from a power supply into a plasma. Microwave discharge plasmas are achieved by directly coupling microwave energy through a microwave-passing window into a discharge chamber containing a plasma gas. Plasmas are typically contained within chambers that are composed of metallic materials such as aluminum or dielectric materials such as quartz, sapphire, yttrium oxide, a zirconium oxide, and/or an aluminum nitride.

There are applications in which a plasma or an excited gas may not be compatible with the reactive gas generator and/or the semiconductor processing system. For example, in some cases during semiconductor manufacturing, ions or atoms of fluorine or fluorocarbons are used for etching or removing silicon or silicon oxides from surfaces of semiconductor wafers or for cleaning process chambers. The fluorine ions are chemically reactive and corrosive to process chamber materials. Remote plasma sources have been used for generating atomic fluorine for these processes to avoid process chamber damage. While reducing erosion in the process chamber, erosion occurs in the remote plasma sources. In another example, atomic oxygen is used to remove photoresist from a semiconductor wafer by converting the photoresist to volatile CO₂ and H₂O byproducts. Atomic oxygen is typically produced by dissociating O₂ (or a gas containing oxygen) with a plasma in a plasma chamber of a reactive gas generator. The plasma chamber can be made of quartz, sapphire, and/or aluminum. The plasma chamber can include dielectric materials such as yttrium oxide, zirconium oxide, and/or aluminum nitride. The plasma chamber can include a metal vessel coated with a dielectric material. Atomic fluorine is often used in conjunction with atomic oxygen because the atomic fluorine accelerates the photoresist removal process. Fluorine is generated by, for example, dissociating NF₃ or CF₄ with the plasma in the plasma chamber. Fluorine, however, is highly corrosive and can adversely react with an aluminum chamber.

A need therefore exists for improved plasma chambers that are less susceptible to the corrosive affects of excited gases located in the plasma chamber.

### SUMMARY

The invention, in one aspect, features a method for creating a protective layer over a surface of an object (for use in, for example, a semiconductor processing system) comprising aluminum and magnesium. The method includes oxidizing the surface of the object using a plasma electrolytic oxidation process. The method also includes generating a halogen-comprising plasma by exciting a gas comprising a halogen. The method also includes exposing the oxidized surface to the halogen-comprising plasma or excited gas.

In some embodiments, oxidizing the surface of the object using the plasma electrolytic process comprises immersing the object in an electrolytic solution lacking potassium hydroxide and sodium hydroxide. In some embodiments (e.g., semiconductor processing applications), an electrolytic solution that does not contain potassium and sodium is desired because semiconductors are sensitive to contamination of potassium or sodium. In some embodiments, the halogen-comprising gas is selected from the group consisting of NF₃, F₂, CF₄, C₂F₆, C₃F₈, SF₆, Cl₂, ClF₃, and Br₂ and BrCl. In some embodiments, the object comprising aluminum and magnesium is an aluminum alloy with magnesium content between about 0.1% to about 6% by weight. In some embodiments, exposing the oxidized surface to the halogen-comprising plasma or excited gas occurs while a semiconductor process is conducted using a plasma reactor. In come embodiments, a plasma reactor is used to generate the halogen-comprising plasma and the object is part of an interior surface of the plasma reactor.

The invention, in another aspect, features a method for preparing an object for use in a semiconductor processing system. The method includes providing an object comprising aluminum and magnesium. The method also includes oxidizing the surface of the object using a plasma electrolytic oxidation process for subsequent exposure to a halogen-comprising plasma or excited gas, to create a protective layer over the surface of the object.

The invention, in another aspect, features an article of manufacture used in a semiconductor processing system having a coating with a dielectric strength greater than 20 volts DC per micron. The article of manufacture includes an object comprising aluminum and magnesium. The article of manufacture also includes a protective layer over a surface of the object formed by oxidizing the surface of the object using a plasma electrolytic oxidation process, and exposing the oxidized surface to a halogen-comprising plasma or excited gas generated by a reactive gas generator.

The invention, in another aspect, features a system for creating a protective layer over a surface of an object comprising aluminum and magnesium. The system includes means for oxidizing the surface of the object using a plasma electrolytic oxidation process. The system also includes means for generating a halogen-comprising plasma by exciting a gas comprising a halogen; and means for exposing the oxidized surface to the halogen-comprising plasma or excited gas.

The invention, in another aspect, features a plasma chamber for use with a reactive gas source. The plasma chamber includes an inlet for receiving a gas. The plasma chamber also includes at least one plasma chamber wall for containing the gas, the plasma chamber wall comprising aluminum and magnesium and a protective layer over a surface of the object formed by, oxidizing the surface of the object using a plasma electrolytic oxidation process, and exposing the oxidized surface to a halogen-comprising plasma or excited gas. The plasma chamber also includes an outlet for outputting a reactive gas generated by the interaction of the plasma and the gas.

The invention, in another aspect, features a method for manufacturing a plasma chamber. The method includes providing a chamber for containing a gas, the chamber comprising an inlet for receiving a gas and an outlet for outputting a reactive gas generated by the interaction of a plasma and the gas, the chamber comprising aluminum and magnesium. The method also includes oxidizing at least one surface of the chamber using a plasma electrolytic oxidation process and exposing the oxidized surface to a halogen-comprising plasma or excited.

### BRIEF DESCRIPTION OF THE DRAWINGS

The foregoing and other objects, feature and advantages of the invention, as well as the invention itself, will be more fully understood from the following illustrative description, when read together with the accompanying drawings which are not necessarily to scale.

FIG. 1 is a flow chart illustrating a method for creating a protective layer over a surface of an object, according to an illustrative embodiment of the invention.

FIG. 2A is a graphical illustration of spectral analysis results conducted on an object process using a conventional anodization process.

FIG. 2B is a graphical illustration of spectral analysis results conducted on an object in which a second embodiment of the invention was applied to the object.

FIG. 2C is a graphical illustration of spectral analysis results conducted on an object in which a second embodiment of the invention was applied to the object.

FIG. 3 is a graphical illustration of dielectric strength for the objects of FIGS. 2A and 2B.

FIG. 4A is a schematic illustration of a reactive gas source used to perform a step in a process for creating a protective layer over a surface of a plasma chamber, according to an illustrative embodiment of the invention.

FIG. 4B is a schematic illustration of a reactive gas source used to perform a step in a process for creating a protective layer over a surface of a plasma chamber, according to an illustrative embodiment of the invention.

### DETAILED DESCRIPTION

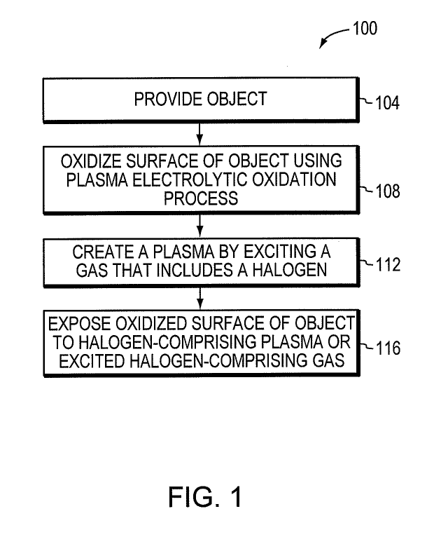

FIG. 1 is a flow chart illustrating a method 100 for creating a protective layer over a surface of an object (e.g., an object for use in a semiconductor processing system), according to an illustrative embodiment of the invention. The method 100 includes providing an object 104 that includes aluminum and magnesium. The method 100 also includes oxidizing a surface of the object using a plasma electrolytic oxidation process 108 to produce an oxidized surface over the surface of the object.

Embodiments of the invention are useful for creating a protective layer over the surfaces of objects used in semiconductor processing. The protective layer can minimize surface erosion (e.g., melting, vaporization, sublimation, sputtering of the material beneath the protective layer) from interior walls of plasma sources. Minimizing surface erosion ultimately minimizes particle generation and contamination of the processes performed in a semiconductor processing system. The protective layer also can reduce the loss of reactive gases that could otherwise occur due to surface recombination of the reactive gas on plasma chamber walls.

The protective layer also broadens the types of plasma chemistries that can be operated in a plasma source. The protective layer makes the plasma chamber better capable of operating (e.g., producing fewer contaminants) in hydrogen, oxygen or nitrogen based chemistries (e.g., H₂O, H₂, O₂, N₂,), halogen based chemistries (e.g., NF₃, CF₄, C₂F₆, C₃F₈, SF₆, Cl₂, ClF₃, Br) and in a mixture and/or rapid cycling of halogen, hydrogen, oxygen or nitrogen based chemistries and Ar-ignition steps. The protective layer therefore extends operation of the plasma sources to higher power levels, improves the dielectric breakdown voltage of the object through the presence of the layer, and ultimately lowers product cost and cost of ownership.

Plasma electrolytic oxidation (also referred to as micro arc oxidation) is an electrochemical process for creating an oxide layer on the surface of metals. The oxide layer is created by immersing a metal (e.g., aluminum) substrate in a low concentrate alkaline electrolytic solution and passing a pulsed AC current through the electrolytic solution. A plasma discharge is formed on the substrate surface in response to the pulsed AC current. The discharge converts the metal surface into a dense, hard oxide (e.g., predominantly alumina in the case where the substrate is aluminum). An elemental co-deposition process occurs simultaneously. The process incorporates other alloy elements from the substrate into the oxidized layer (e.g., drawing magnesium (Mg) from the aluminum alloy substrate into the oxidized layer). In some embodiments, the object fabricated from an aluminum alloy with magnesium content between about 0.1% to about 6% by weight. A thick, uniform coating is formed over the surface of the substrate in response to the electrochemical and physical reactions occurring in the process.

In general, the oxide layer consists of three layers: a porous external layer, a hard layer, and a transition layer. The porous external layer occupies approximately 30%-40% of the total thickness of the oxide layer. The hard layer is a partially crystallized layer of the oxide. The transition layer is a thin layer located between the metal substrate and the ceramic coating. Various electrolytic solutions can be used to form the dense oxide layer in the plasma electrolytic oxidation process. In one embodiment, in which the metal substrate is to be used in a semiconductor processing application, it is beneficial for the oxide layer to be free of potassium (K) and sodium (Na); it is therefore desirable for the electrolytic solutions to also be free of potassium and sodium. Some common electrolytic solutions include potassium hydroxide and sodium hydroxide. It is therefore beneficial in some embodiments for the electrolytic solution not to include potassium hydroxide or sodium hydroxide. The plasma electrolytic oxidation process is a commercially available process. One supplier that offers the process as a service is Keronite International Ltd. (Granta Park, Great Abington, Cambridge, CB21 6GP, UK).

While anodization is also a process that forms an oxide layer on the surface of metals, plasma electrolytic oxidation creates a harder, less porous and more corrosion resistant layer. Plasma electrolytic oxidation involves the application of higher electrical potentials than used with conventional anodization (several hundred volts for plasma electrolytic oxidation as compared with several tens of volts for conventional anodization). The high electrical potentials applied in plasma electrolytic oxidation results in electrical discharges that produce a plasma at the surface of the object. The plasma modifies and enhances the structure of the oxide layer. Plasma electrolytic oxidation is a chemical process that converts the metal in the object into its oxide. The oxide grows both inwards and outwards from the original metal surface of the object. A wide range of metals and metal alloys can be processed using plasma electrolytric oxidation, including all aluminium alloys and cast alloys. Step 108 prepares the object for subsequent processing in step 112 to ultimately create a protective layer over the surface of the object.

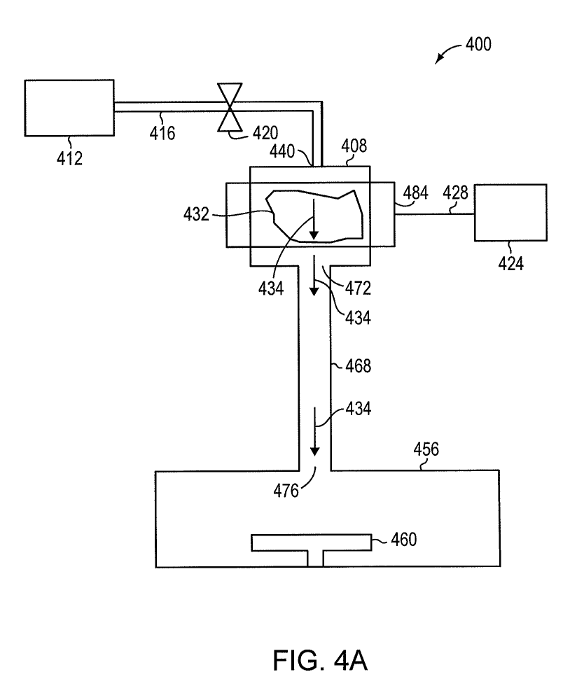

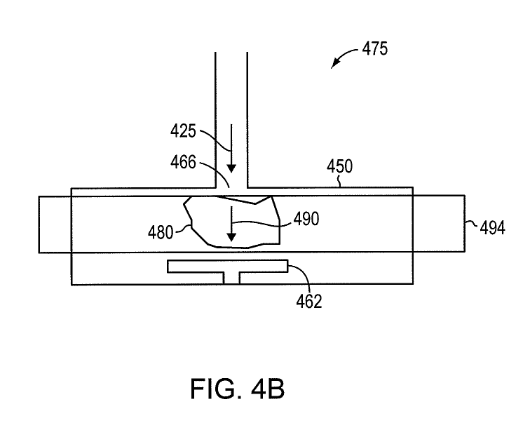

The method 100 also includes generating a halogen-comprising plasma by exciting a gas that includes a halogen 112. Halogens (or halogen elements) are nonmetal elements from group VII and VIIA of the periodic table (e.g., fluorine). Exemplary halogen-comprising gases useful in emboidments of the invention include, for example, NF₃, F₂, CF₄, C₂F₆, C₃F₈, SF₆, Cl₂, ClF₃, and Br₂ and BrCl. In one embodiment, the halogen-comprising gas is excited using a reactive gas generator (e.g., the reactive gas generator of FIG. 4).

The method 100 also includes exposing the oxidized surface of the object to the halogen-comprising plasma and/or halogen-comprising gas 116. When the oxide layer of the object is exposed to the halogen-comprising plasma or excited gas, alloy elements drawn into the oxide layer by the plasma electrolytic oxidation process (see step 108) react with the halogen-comprising plasma or excited gas.

In one embodiment, the object is an aluminum alloy that includes magnesium. During the plasma electrolytic oxidation process, magnesium is drawn into the oxide layer. When the oxide layer (which includes oxides of magnesium) is exposed to an excited gas comprising fluorine, the magnesium oxide reacts with the fluorine to form magnesium fluoride (MgF₂). The magnesium fluoride is created in the oxide layer. The magnesium fluoride forms diffusion bonds with adjoining material layers of the object and encapsulates and protects aluminum and aluminum oxide on the surface of the object from exposure to the fluorine-comprising gas. The magnesium fluoride inhibits the penetration of additional fluorine into the oxide layer and provides protection for the oxide layer and the base aluminum alloy.

In one embodiment, the protective layer is created over a surface of an object that is part of an interior surface of a plasma reactor running a halogen-based process. Generating the plasma and exciting the gas that includes halogen (step 112) and exposing the oxidized surface of the object to the halogen-comprising plasma or excited gas (step 116) occur while running the halogen-based process. In some embodiments, method 100 is implemented in this manner because the oxidized surface gains resistance to halogen attack while running a halogen-based semiconductor process.

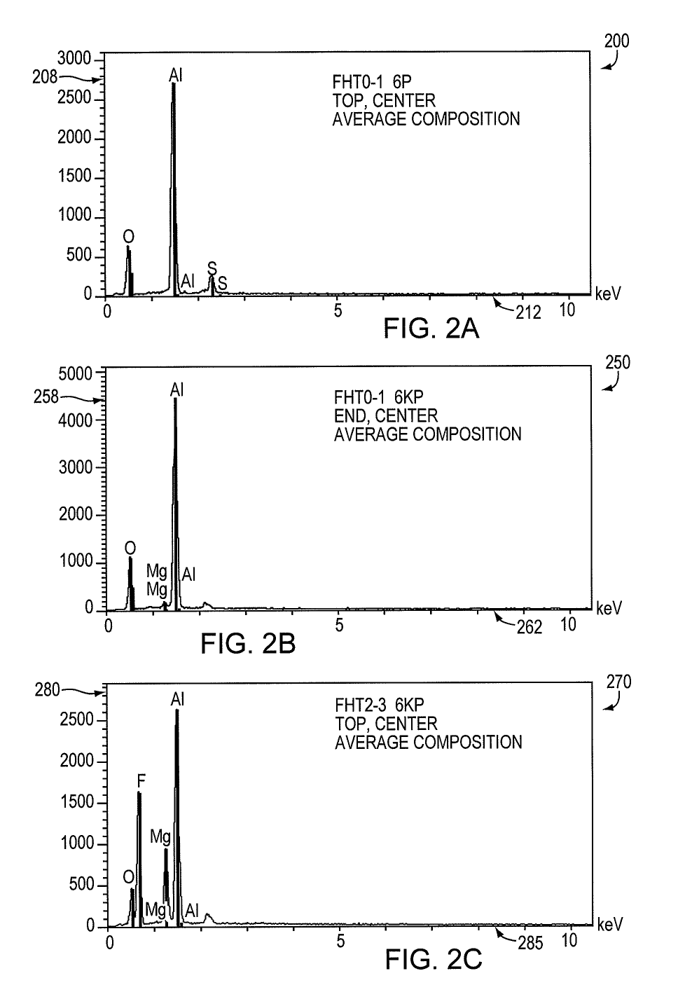

FIGS. 2A is a plot of the spectrum of an Energy Dispersive X-ray Spectroscopy (EDS) analysis from tests conducted on an object that was anodized using a conventional Type III hard anodization process. The spectrum in FIG. 2A is a plot 200 of the x-ray signal counts 208 (Y-axis) versus the x-ray energy in keV (kilo electron volt) 212 (X-axis) of the object being analyzed. The object used is a rod of aluminum 6061 alloy. The thickness of the oxidation layer on the object is approximately 50 μm. The object was not exposed to a plasma prior to the EDS analysis. The x-ray emission was generated with an 18 keV electron beam, limiting the detection thickness to within about 2-3 μm of the anodized aluminum surface. Plot 200 shows that the oxidized object includes aluminum (Al) and oxygen (O). The amount of magnesium is under the detection limit of the analysis system.

FIGS. 2B and 2C are plots of spectra of Energy Dispersive X-ray Spectroscopy (EDS) analysis from tests conducted on objects in which different embodiments of the invention were applied to the objects. The spectrum in FIG. 2B is a plot 250 of the x-ray signal counts 258 (Y-axis) versus the x-ray energy in keV (kilo electron volt) 262 (X-axis) of the object being analyzed. The object used in this analysis was a rod of aluminum 6061 alloy (6061 alloy contains approximately 1% magnesium) that was processed using a plasma electrolytic oxidation process by Keronite International Ltd. The thickness of the oxide layer is approximately 50 μm. The object was not exposed to a plasma prior to the EDS analysis. Plot 250 shows that the oxidized object includes the following elements: oxygen (O), aluminum (Al), and magnesium (Mg).

The spectrum in FIG. 2C is a plot 270 of the x-ray signal counts 280 (Y-axis) versus the x-ray energy in keV (kilo electron volt) 285 (X-axis) of the object being analyzed. The object is a rod of aluminum 6061 alloy that was processed by Keronite International Ltd. using the same plasma electrolytic oxidation process used on the object in FIG. 2B. After processing the object using the plasma electrolytic oxidation process, the object was exposed to an NF₃ plasma for 50 hours prior to conducting the EDS analysis. Plot 270 shows that the oxidized object includes the following elements: oxygen (O); aluminum (Al); magnesium (Mg) and fluorine (F). The amount of magnesium in the object in FIG. 2C (approximately 1000 x-ray signal counts) is significantly higher than the amount of magnesium in the object in FIG. 2B (approximately 100 x-ray signal counts). Fluorine is present in the object in FIG. 2C because fluorides of aluminum and magnesium are formed during exposure to the NF₃ plasma. Magnesium fluoride is known to form diffusion bonds with adjoining material layers in aluminum or aluminum oxide. The magnesium fluoride encapsulates and protects aluminum and aluminum oxide from further exposure to the fluorine-comprising gas. When aluminum oxides are removed by the NF₃ plasma, the relative concentration of magnesium fluoride or magnesium oxide increases on the surface of the object. The magnesium fluoride inhibits the penetration of additional fluorine into the oxide layer and provides protection for the oxide layer and the base aluminum alloy.

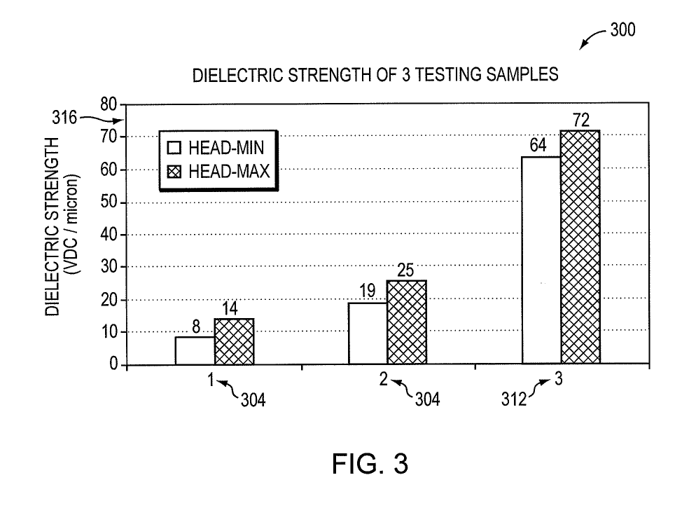

FIG. 3 is a graphical illustration of dielectric strength of the oxidized layers on three objects. Plot 300 of FIG. 3 is a plot of the dielectric strength of the three objects 304, 308 and 312. Object 304 is an object that was oxidized using a conventional oxidation process to create an anodized surface on the object. Objects 308 and 312 have surfaces that were oxidized using a plasma electrolytic oxidation process performed by Keronite International using different electrolytes. The Y-axis 316 of the plot 300 is the dielectric strength in volts/μm. The maximum and minimum value of the dielectric strength was determined based on the breakdown voltage of each object at five locations on each object. Dielectric strength was calculated as the measured breakdown voltage divided by the thickness of the oxide layer measured at the five locations on the object. The dielectric strength of object 304 was less than about 14 volts DC/μm. The dielectric strength of object 308 was greater than about 19 volts DC/μm. The dielectric strength of object 312 was greater than about 64 volts DC/μm. The breakdown voltage was measured using a Biddle AC/DC High-Pot Tester (model #230425) manufactured by Megger Group Limited (Dallas, Tex.). The thickness of the oxide layer was measured using a DualScope® MP20 thickness measurement unit manufactured by Fischer Technology, Inc. (Windsor, Conn.). The dielectric strength of the objects with surfaces that were treated using the plasma electrolytic oxidation process (objects 308 and 312) was greater than about 20 volts DC/μm.

FIG. 4A is partial schematic representation of a reactive gas generator system 400 for exciting gases, according to an illustrative embodiment of the invention. The reactive gas generator system 400 includes a plasma gas source 412 connected via a gas line 416 to an inlet 440 of a plasma chamber 408. A valve 420 controls the flow of plasma gas (e.g., O₂, N₂, Ar, NF₃, F₂, H₂ and He) from the plasma gas source 412 through the gas line 416 and into the inlet 440 of the plasma chamber 408. A plasma generator 484 generates a region of plasma 432 within the plasma chamber 408. The plasma 432 comprises the plasma excited gas 434, a portion of which flows out of the chamber 408. The plasma excited gas 434 is produced as a result of the plasma 432 heating and activating the plasma gas. In this embodiment, the plasma generator 484 is located partially around the plasma chamber 408.

The reactive gas generator system 400 also includes a power supply 424 that provides power via connection 428 to the plasma generator 484 to generate the plasma 432 (which comprises the excited gas 434) in the plasma chamber 408. The plasma chamber 408 can be formed or fabricated from, for example, a metallic material such as aluminum or a refractory metal, a dielectric material such as quartz or sapphire, or a coated metal such as anodized aluminum. In some embodiments, the plasma gas is used to both generate the plasma 432 and to generate the excited gas 434.

The plasma chamber 408 has an outlet 472 that is connected via a passage 468 to an input 476 of a process chamber 456. The excited gas 434 flows through passage 468 and into the input 476 of the process chamber 456. A sample holder 460 positioned in the process chamber 456 supports a material that is processed by the excited gas 434. In one embodiment, the excited gas 434 facilitates etching of a semiconductor wafer located on the sample holder 460 in the process chamber 456.

The plasma source 484 can be, for example, a DC plasma generator, radio frequency (RF) plasma generator or a microwave plasma generator. The plasma source 484 can be a remote plasma source. By way of example, the plasma source 484 can be an ASTRON® remote plasma source manufactured by MKS Instruments, Inc. of Wilmington, Mass.

In one embodiment, the plasma source 484 is a toroidal plasma source and the chamber 408 is a chamber made from an aluminum alloy that includes magnesium. In other embodiments, alternative types of plasma sources and chamber materials may be used.

The power supply 424 can be, for example, an RF power supply or a microwave power supply. In some embodiments, the plasma chamber 408 includes a means for generating free charges that provides an initial ionization event that ignites the plasma 432 in the plasma chamber 408. The initial ionization event can be a short, high voltage pulse that is applied to the plasma chamber 408. The pulse can have a voltage of approximately 500-10,000 volts and can be approximately 0.1 microseconds to 100 milliseconds long. A noble gas such as argon can be inserted into the plasma chamber 408 to reduce the voltage required to ignite the plasma 432. Ultraviolet radiation also can be used to generate the free charges in the plasma chamber 408 that provide the initial ionization event that ignites the plasma 432 in the plasma chamber 408.

In one embodiment of the invention, the reactive gas generator system 400 is used to excite a gas comprising halogen for use as described previously herein (e.g., with respect to step 112 of FIG. 1). An object comprising aluminum and magnesium is processed using a plasma electrolytic oxidation process (e.g., step 108 of FIG. 1) to oxidize at least one surface of the object.

In one embodiment, the oxidized object was installed in the plasma chamber 408 and exposed to the plasma 432. In one embodiment, an ASTRON®ex remote plasma source manufactured by MKS Instruments, Inc. of Wilmington, Mass. was used as the plasma source 484. The oxidized object was exposed to a NF₃ plasma generated by the plasma source to produce magnesium fluoride on the surface. The NF₃ flow rate was 3 slm and chamber pressure was 2.9 torr. The electric power provided to the plasma was approximately 6.5 kW.

In another embodiment of the invention, the reactive gas generator system 400 is used to excite a gas comprising halogen for use as described previously herein (e.g., with respect to step 112 of FIG. 1). The plasma chamber 408 is the object that is processed using a plasma electrolytic oxidation process (e.g., step 108 of FIG. 1). In this embodiment, the plasma chamber 408 is constructed from an aluminum alloy that includes magnesium. A plasma electrolytic oxidation process is used to create the oxide layer on the interior surfaces of the plasma chamber 408. The plasma chamber 408 is then installed in the reactive gas generator system 400.

The plasma source 412 provides NF₃ as the plasma gas to the plasma chamber 408. Plasma 432 is generated using the NF₃. The plasma 432 generates the excited plasma gas 434 in the chamber 408. The oxidized interior surfaces of the plasma chamber 408 are therefore exposed to the fluorine-comprising plasma 432 and excited gas 434 (which comprises fluorine). The oxidized surfaces of the plasma chamber 408 are exposed to the plasma 432 and excited gas 434, similarly as described above with respect to FIG. 1. The magnesium oxide in the oxide layer on the walls of the plasma chamber 408 reacts with the fluorine to form magnesium fluoride (MgF₂). The magnesium fluoride is created in the oxide layer.

In another embodiment of the invention, the reactive gas generator system 400 is used to create plasma 432 by exciting a gas comprising halogen. The interior surfaces of gas passage 468 and/or process chamber 456 are the objects processed using a plasma electrolytic oxidation process (e.g., step 108 of FIG. 1). In this embodiment, the gas passage 468 and/or process chamber 456 are constructed from an aluminum alloy that includes magnesium. A plasma electrolytic oxidation process is used to create the oxide layer on the interior surfaces of passage 468 or process chamber 456. The plasma chamber 408 is installed in the reactive gas generator system 400. The plasma gas source 412 provides NF₃ (as the plasma gas) to the plasma chamber 408. Plasma 432 is generated using the NF₃. The plasma 432 generates the excited plasma gas 434 which subsequently flows through passage 468 and process chamber 456. The oxidized interior surfaces of the passage 468 and process chamber 456 are therefore exposed to the excited gas 434 (which comprises fluorine). The oxidized surfaces of the passage 468 and process chamber 456 are exposed to the excited gas 434, similarly as described above with respect to FIG. 1. The magnesium oxide in the oxide layer on the walls of the passage 468 and process chamber 456 reacts with the fluorine to form magnesium fluoride (MgF₂).

FIG. 4B is partial schematic representation of an in-situ plasma system 475. The plasma gas 425 (e.g., a gas comprising a halogen) is provided, via input 466, to the plasma chamber 450, which is also the process chamber. A plasma 480 is generated inside the chamber 450 by a plasma reactor 494. A sample holder 462 positioned in the process chamber 450 supports a material that is processed by the plasma 480 and excited gas 490. In one embodiment, the object is placed on the sample holder 462. In another embodiment, the object is itself the process chamber 450. A plasma electrolytic oxidation process is used to create the oxide layer on the object. The oxidized surface of the object is exposed to the halogen-comprising plasma 480 and excited gas 490, similarly as described above with respect to FIG. 1.

Variations, modifications, and other implementations of what is described herein will occur to those of ordinary skill in the art without departing from the spirit and the scope of the invention as claimed. Accordingly, the invention is to be defined not by the preceding illustrative description but instead by the spirit and scope of the following claims.

1. A method for creating a protective layer over a surface of an object comprising aluminum and magnesium for use in a semiconductor processing system, the method comprising:
oxidizing the surface of the object using a plasma electrolytic oxidation process;
generating a halogen-comprising plasma by exciting a gas comprising a halogen; and
exposing the oxidized surface to the halogen-comprising plasma or excited gas.

2. The method of claim 1, wherein the halogen-comprising gas is selected from the group consisting of NF₃, F₂, CF₄, C₂F₆, C₃F₈, SF₆, Cl₂, ClF₃, and Br₂ and BrCl.

3. The method of claim 1, wherein the object comprising aluminum and magnesium is an aluminum alloy with magnesium content between about 0.1% to about 6% by weight.

4. The method of claim 1, wherein the gas comprising a halogen is excited using a reactive gas generator.

5. The method of claim 1, wherein a plasma reactor is used to generate the halogen-comprising plasma and the object is part of an interior surface of a plasma reactor.

6. The method of claim 1, wherein exposing the oxidized surface to the halogen-comprising plasma or excited gas occurs while a semiconductor process is conducted using a plasma reactor.

7. A method for preparing an object for use in a semiconductor processing system, the method comprising:
providing an object comprising aluminum and magnesium; and
oxidizing the surface of the object using a plasma electrolytic oxidation process for subsequent exposure to a halogen-comprising plasma or excited gas, to create a protective layer over the surface of the object.

8. An article of manufacture used in a semiconductor processing system having a coating with a dielectric strength greater than 20 volts DC per micron, article of manufacture comprising:
an object comprising aluminum and magnesium; and
a protective layer over a surface of the object formed by,
oxidizing the surface of the object using a plasma electrolytic oxidation process, and
exposing the oxidized surface to a halogen-comprising plasma or excited gas generated by a reactive gas generator.

9. A system for creating a protective layer over a surface of an object comprising aluminum and magnesium for use in a semiconductor processing system, the system comprising:
means for oxidizing the surface of the object using a plasma electrolytic oxidation process;
means for generating a halogen-comprising plasma by exciting a gas comprising a halogen; and
means for exposing the oxidized surface to the halogen-comprising plasma or excited gas.

10. A plasma chamber for use with a reactive gas source, the plasma chamber comprising:
an inlet for receiving a gas;
at least one plasma chamber wall for containing the gas, the plasma chamber wall comprising aluminum and magnesium and a protective layer over a surface of the object formed by, oxidizing the surface of the object using a plasma electrolytic oxidation process, and exposing the oxidized surface to a halogen-comprising plasma or excited gas; and
and an outlet for outputting a reactive gas generated by the interaction of the plasma and the gas.

11. A method for manufacturing a plasma chamber, the method comprising:
providing a chamber for containing a gas, the chamber comprising an inlet for receiving a gas and an outlet for outputting a reactive gas generated by the interaction of a plasma and the gas, the chamber comprising aluminum and magnesium;
oxidizing at least one surface of the chamber using a plasma electrolytic oxidation process and exposing the oxidized surface to a halogen-comprising plasma or excited gas.

12. The method of claim 1, wherein the object is part of an interior surface of a plasma reactor, the method further comprising operating the plasma reactor in hydrogen, oxygen or nitrogen based chemistries.

13. The method of claim 11, wherein the chamber is part of a plasma reactor, the method further comprising operating the plasma reactor in hydrogen, oxygen or nitrogen based chemistries.
